(19) United States
(12) Patent Application Publication
(10) Pub. No.: US 2011/0204905 A1
(43) Pub. Date: Aug. 25, 2011

(54) OCCUPANT DETECTION SYSTEM AND CONTROL METHOD OF OCCUPANT DETECTION SYSTEM

(75) Inventors: Hideki UNO, Toyota-shi (JP); Yasuhiro ISHIGURO, Toyota-shi (JP)

(73) Assignee: TOYOTA BOSHOKU KABUSHIKI KAISHA, Aichi-ken (JP)

(21) Appl. No.: 13/033,781

(22) Filed: Feb. 24, 2011

(30) Foreign Application Priority Data
Feb. 25, 2010 (JP) 2010-040927

(51) Int. Cl. G01R 27/08

(52) U.S. Cl. 324/705

(57) ABSTRACT

An occupant detection system includes an electrode provided in a vehicle seat for detecting the capacitance derived from a human body, an oscillator circuit that supplies a sinusoidal signal S₀ to the electrode via a resistive element, a first comparator circuit that digitizes the signal S₀ using a threshold corresponding to a given phase so as to produce a phase signal D₀, a second comparator circuit that detects the potential of the electrode as an electrode signal S₁, and digitizes the electrode signal S₁ using a threshold corresponding to a phase that is substantially the same as the given phase of the signal S₀ so as to produce an electrode phase signal D₁, and a control circuit that measures delay times of the electrode phase signal D₁ relative to those of the phase signal D₀, so as to determine the presence of a seated occupant based on the delay times.

### INCORPORATION BY REFERENCE

The disclosure of Japanese Patent Application No. 2010-040927 filed on Feb. 25, 2010 including the specification, drawings and abstract is incorporated herein by reference in its entirety.

### BACKGROUND OF THE INVENTION

1. Field of the Invention

The invention relates to an occupant detection system and a control method of the occupant detection system for determining whether an occupant is present in a vehicle seat, and more particularly to such an occupant detection system that is able to determine the presence of a seated occupant with stability even when the vehicle seat is in a wet condition.

2. Description of the Related Art

In automobiles, detected information as to whether an occupant is present in a seat is used for determining whether an air-bag is to be deployed or inflated. A vehicle air-bag system is controlled so that an air-bag deploys when an occupant (adult) is present in a seat, such as a passenger's seat, at the time of a collision of the vehicle, and the air-bag does not deploy when no occupant is present in the seat. While various methods for detecting a seating condition of an occupant have been used, a capacitance type occupant detection system is known, for example. Since a human body is a dielectric, the capacitance that arises between a detection electrode provided in a seat bottom or seatback portion of the seat and the ground of the vehicle varies depending upon whether an occupant is present in the seat or no occupant is present in the seat. The system detects the variation in the capacitance by detecting a change of voltage or current or disturbances in an electric field, for example, so as to determine whether an occupant is seated. Also, an occupant detection system is known which detects disturbances in a very weak electric field generated at around an antenna electrode provided in a seat, in the form of a change in current that passes through the antenna electrode (see Japanese Patent No. 3346464).

In the occupant detection system of the type as described above, the detection electrode or electrodes used for detecting an occupant is/are disposed on the surface of the vehicle seat or immediately below the seat surface. Therefore, if the seat gets wet, the impedance around the detection electrode may change, or a wet portion may act as an antenna electrode, which may result in a problem that a determination as to the presence of a seated occupant or whether the seated occupant is an adult or a child is erroneously made. As a measure against the problem, an example of occupant detection system including a moisture sensor is disclosed (see Japanese Patent Application Publication No. 2002-347498 (JP-A-2002-347498)). Also, another example of occupant detection system is disclosed which applies a load current to an antenna electrode provided in the seat so as to generate a very weak electric field, while measuring a potential current that passes through the antenna electrode, and calculates the impedance and phase difference from the load current and the potential current, so as to detect a seated occupant based on the calculated impedance and phase difference (see Japanese Patent Application Publication No. 2007-240515 (JP-A-2007-240515)). The occupant detection system disclosed in this publication is less likely or unlikely to suffer from erroneous detection of an occupant due to a wet condition of the seat.

As described above, the conventional occupant detection system that detects whether an occupant is present in the seat by measuring the capacitance between electrodes provided in the vehicle seat, current, resistance, etc. suffers from a problem that erroneous detection may occur when the seat is in a wet condition. Even where the system is provided with a moisture sensor, and is adapted to change a measuring method(s) or criteria for use in occupant detection, according to the moisture or water level, the arrangement of the electrodes and processing for determination (occupant detection) are complicated, which also results in an increase in the cost. Even in the known occupant detection system that calculates the impedance and phase difference from the load current and potential current of the antenna electrode provided in the seat, and detects an occupant based on the calculated impedance and phase difference, in order to prevent erroneous detection due to wetting of the seat, there is a need to provide electrodes for proximity measurement, which are used for measuring the impedance and the phase difference. Also, a complicated operation or processing needs to be performed to calculate the impedance and the phase difference from the measured load current and potential current, determine a threshold value based on the calculated phase difference, and compares the impedance with the threshold value.

### SUMMARY OF THE INVENTION

The invention provides an occupant detection system that is able to determine the presence or absence of a seated occupant with stability even when a vehicle seat is wet, through simple arrangement and processing, and a control method of the occupant detection system.

An occupant detection system according to a first aspect of the invention includes a detection electrode provided in at least one of a seat bottom and a seatback of a vehicle seat, an oscillator circuit that supplies a reference signal comprising a sinusoidal wave, to the detection electrode, via a resistive element, a first comparator circuit that produces a binary reference phase signal by comparing the voltage of the reference signal with a first threshold value, a second comparator circuit that detects the potential of the detection electrode as an electrode signal, and produces a binary electrode phase signal by comparing the electrode signal with a second threshold value, and a control circuit. The second threshold value is set so that a phase of the reference signal at a point at which the reference signal passes the first threshold value is substantially the same as that of the electrode signal at a point at which the electrode signal passes the second threshold value. The control circuit includes a measuring unit that measures a delay time of a rise of the electrode phase signal relative to a rise of the reference phase signal as a rise delay time, and measures a delay time of a fall of the electrode phase signal relative to a fall of the reference phase signal as a fall delay time, and a detecting unit that detects an occupant based on the rise delay time and the fall delay time.

The detecting unit may determine the presence of a seated occupant based on the sum of the rise delay time and the fall delay time.

Also, the electrode signal may be produced as a signal having substantially the same amplitude as that of the reference signal, and the second threshold value may be set to the same value as the first threshold value.

The detection electrode may be a conductive cloth, and the conductive cloth may be formed as a surface material of the seat, or may be disposed immediately below the surface material.

The conductive cloth may be a woven fabric into which conductive fibers are woven at fixed intervals.

According to a second aspect of the invention, there is provided a control method of an occupant detection system including a detection electrode provided in at least one of a seat bottom and a seatback of a vehicle seat, an oscillator circuit that supplies a reference signal comprising a sinusoidal wave, to the detection electrode, via a resistive element, a first comparator circuit that produces a binary reference phase signal by comparing the voltage of the reference signal with a first threshold value, and a second comparator circuit that detects the potential of the detection electrode as an electrode signal, and produces a binary electrode phase signal by comparing the electrode signal with a second threshold value, wherein the second threshold value is set so that a phase of the reference signal at a point at which the reference signal passes the first threshold value is substantially the same as that of the electrode signal at a point at which the electrode signal passes the second threshold value. The control method of the occupant detection system includes a process of measuring a delay time of a rise of the electrode phase signal relative to a rise of the reference phase signal as a rise delay time, and measuring a delay time of a fall of the electrode phase signal relative to a fall of the reference phase signal as a fall delay time, and a process of detecting a wet condition of the seat based on the rise delay time and the fall delay time.

The occupant detection system according to the first aspect of the invention is able to easily obtain a phase difference between the reference signal produced by the oscillator circuit and the potential of the detection electrode. Since the control circuit includes the measuring unit and the detecting unit as described above, the system is able to detect a seated occupant with stability or reliability, by using the measured rise delay time and fall delay time, while detecting the degree of disturbance, such as the degree of wetness of the seat, or without being influenced by the disturbance. Also, there is no need to use a special sensor or arrangement for preventing erroneous detection due to wetting, for example, and a seated occupant can be detected only by using one detection electrode. In the case where the detecting unit determines the presence of a seated occupant based on the sum of the rise delay time and the fall delay time, the presence of the seated occupant can be extremely simply and stably determined since the sum is not influenced by a wet condition of the seat, but the sum represents a value corresponding to the capacitance of an object on the seat. In the case where the electrode signal is produced as a signal having substantially the same amplitude as that of the reference signal, and the second threshold value is set to the same value as the first threshold value, the occupant detection system that is not affected by wetting of the seat, or the like, can be achieved by a further simpler circuit configuration. In the case where the detection electrode is a conductive cloth, and the conductive cloth is formed as a surface material of the seat or is disposed immediately below the seat surface, the occupant detection system operates with stability or reliability even when the conductive cloth is in a wet condition, and the texture and breathability of the seat do not deteriorate. Also, the detection electrode may be formed integrally as a part of the exterior of the seat. If the conductive cloth is a woven fabric into which conductive fibers are woven at fixed intervals, the occupant detection system is advantageous in the use of the detection electrode that is excellent in terms of durability and cost efficiency or economy.

According to the control method of the occupant detection system of the second aspect of the invention, the phase difference between the reference signal and the potential of the detection electrode can be easily obtained with a simple arrangement. The control method of the occupant detection system includes the process of measuring the delay time of a rise of the electrode phase signal relative to a rise of the reference phase signal as the rise delay time, and measuring the delay time of a fall of the electrode phase signal relative to a fall of the reference phase signal as the fall delay time, and the process of detecting a wet condition of the seat based on the rise delay time and the fall delay time. Therefore, a condition of disturbance, such as wetting of the seat, can be determined through simple processing. It is thus possible to change the operation of the occupant detection system, or change the method of determining the presence of an occupant in the seat or reference values for use in the determination, or correct measurement values, in accordance with the degree of disturbance, such as the degree of wetness of the seat. Also, there is no need to use a special sensor or arrangement for curbing or preventing erroneous detection due to wetting, for example.

### BRIEF DESCRIPTION OF THE DRAWINGS

The features, advantages, and technical and industrial significance of this invention will be described in the following detailed description of example embodiments of the invention with reference to the accompanying drawings, in which like numerals denote like elements, and wherein:

FIG. 1 is a schematic diagram showing the general construction of a vehicle seat and its surroundings, including an occupant detection system of the invention;

FIG. 2 is a block diagram showing the configuration of the occupant detection system of the invention;

FIG. 3A to FIG. 3D are timing charts useful for explaining the basic operation of the occupant detection system of the invention;

FIG. 4 is a graph indicating the relationship between the capacitance developed at a detection electrode due to the presence of an object on the seat, and the delay time of an electrode phase signal relative to a reference phase signal;

FIG. 5A to FIG. 5D are timing charts useful for explaining the operation of the occupant detection system when there is a disturbance, such as wetting of the seat;

FIG. 6 is a graph indicating the relationship between the amount of water under which the seat is wet, and the delay times of the electrode phase signal relative to the reference phase signal;

FIG. 7 is a graph indicating the relationship between the amount of water under which the seat is wet, and the sum of the rise delay time and fall delay time of the electrode phase signal relative to the reference phase signal;

FIG. 8 is a circuit diagram showing the configuration of an example of oscillator circuit;

FIG. 9 is a circuit diagram showing the configuration of an example of first comparator circuit and second comparator circuit;

FIG. 10A and FIG. 10B are timing charts useful for explaining the operation of one embodiment of the occupant detection system;

FIG. 11A and FIG. 11B are timing charts useful for explaining the operation of the embodiment of the occupant detection system as indicated in FIG. 10A and FIG. 10B in a condition where there is a disturbance, such as wetting of the seat;

FIG. 12A shows graphs indicating the relationships between the amount of water applied to the seat and the rise delay time of the electrode phase signal relative to the reference phase signal;

FIG. 12B shows graphs indicating the relationships between the amount of water applied to the seat and the fall delay time of the electrode phase, signal relative to the reference phase signal;

FIG. 13A and FIG. 13B show graphs indicating the relationships between the amount of water applied to the seat, and the sum of the rise delay time and fall delay time of the electrode phase signal relative to the reference phase signal, which relationships were obtained from measurements; and

FIG. 14 is a flowchart illustrating an example of detecting method implemented by the occupant detection system of the invention.

### DETAILED DESCRIPTION OF EMBODIMENTS

The matters mentioned herein are exemplary ones and those for explaining embodiments of this invention for illustrative purposes, and are stated in order to provide explanations supposed to make the principle of the invention and its conceptual features understood most effectively without difficulty. In this respect, the matters mentioned herein are not intended to indicate structural details of the invention to the extent more than necessary for fundamental understanding of the invention, but are intended to make how some forms of the invention are actually implemented clear to those skilled in the art, through explanation with reference to the drawings.

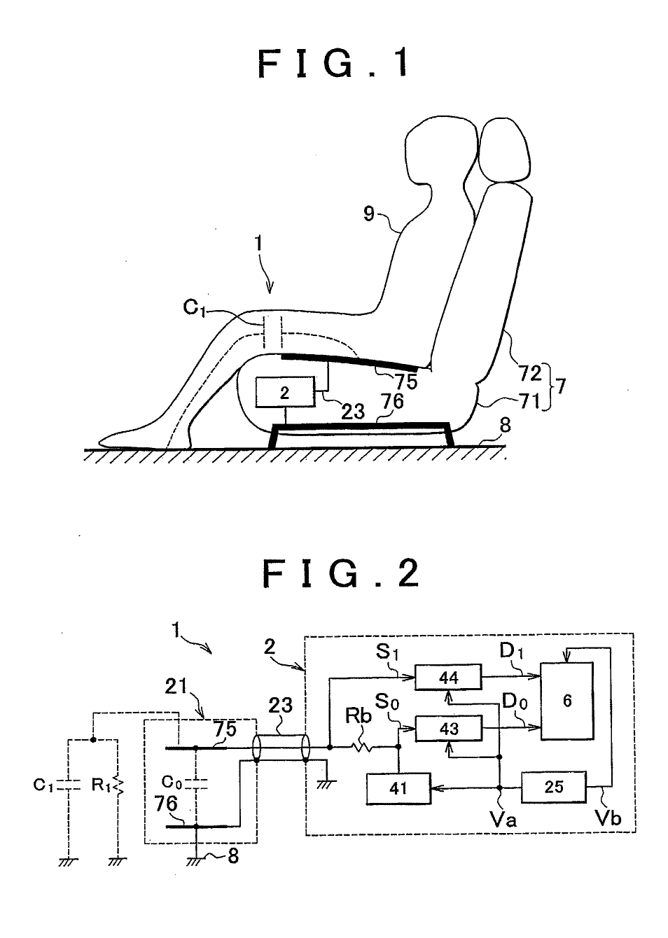

The capacitance between a detection electrode provided in a vehicle seat and the vehicle body varies between the case where the vehicle seat is not occupied (i.e., no occupant is present in the seat) and the case where an occupant is present in the seat. An occupant detection system according to one embodiment of the invention is basically configured to detect an occupant based on a change in a phase difference between sinusoidal reference signal and electrode signal, which change occurs due to the presence of an occupant in the seat. In particular, the occupant detection system detects a seated occupant with stability even in the case where the seat is wet, for example, by devising its measuring and determining methods. FIG. 1 schematically illustrates a vehicle seat incorporating the occupant detection system of the invention, and its surroundings. In FIG. 1, the vehicle seat 7 is a passenger's seat or a rear seat, for example. When an occupant 9 sits in the seat 7, the capacitance C1 arises due to the presence of the occupant's body 9 between the detection electrode 75 and the vehicle body 8. If the capacitance between the detection electrode 75 and the vehicle body 8 changes, a phase difference between a sinusoidal signal (reference signal) supplied to the detection electrode 75 via a resistive element, and a signal (electrode signal) detected at the detection electrode 75, changes. By measuring the phase difference, it is possible to determine the presence or absence of an occupant in the seat. The occupant detection system 1 includes a sensor portion including the detection electrode 75, and an electronic control unit (ECU) 2 that performs measuring and determining operations.

The seat 7 as shown in FIG. 1 consists of a seat bottom 71 and a seatback 72, and is fixed to a floor 8 of the vehicle body via a seat frame 76. The vehicle body 8 is electrically at a ground potential (the vehicle is grounded) that provides a basis of the potential of the detection electrode 75. If the seat frame 76 is made of metal, the seat frame 76 may act as a ground electrode. The interior of the seat bottom 71 of the seat comprises cushioning formed of a urethane foam, or the like, which is placed on the seat frame 76, and the seat bottom 71 is covered with a surface material, such as a woven fabric. Similarly, the seatback 72 is comprised of a seat frame, cushioning, a surface material, and so forth.

The detection electrode 75 for detecting a seated occupant is provided in a top seating portion of the seat bottom 71 of the seat. The detection electrode 75 may provide a part of the surface material with which the seat 7 is covered, or may be placed immediately below the surface material, namely, interposed between the surface material and the cushioning. A wide variety a materials having electrical conductivity may be used for the detection electrode 75. For example, a fabric having conductivity, a cloth formed by weaving metal wires into meshes, a conductive film, a metal plate, or the like, may be used to form the detection electrode 75. Preferably, a conductive cloth may be used as the detection electrode 75. The conductive cloth means a cloth to which electrical conductivity is given, and its material and manufacturing method are not particularly limited. One example of such conductive cloth is produced by using conductive fibers whose surfaces are covered with a metal, such as copper, nickel, or silver. The conductive cloth may be a sheet of woven fabric formed by weaving threads of conductive fibers, or may be a sheet of unwoven fabric formed from conductive fibers by thermal compression, or the like, without weaving the conductive fibers. The conductive cloth may also be formed by covering woven fabric or unwoven fabric using non-conductive threads, with a metal, such as copper, nickel, or silver, by plating, for example. One example of conductive cloth that provides the detection electrode 75 is a sheet of woven fabric into which conductive fibers, such as stainless steel wires, carbon fibers, or plated fibers, are woven as needed. For example, a woven fabric into which conductive fibers, such as stainless steel wires, are woven at intervals of about 1 to 10 mm is used to provide a detection electrode having excellent durability and economical efficiency. The use of the conductive cloth for the detection electrode 75 makes it possible to design the detection electrode as desired, i.e., determine the shape and dimensions of the detection electrode as desired, and permits the detection electrode to be formed integrally with the surface material that forms other portions of the seat. Also, the detection electrode in the form of the conductive cloth does not reduce the breathability of the seat, nor does impair the texture of the seat.

In the occupant detection system of this invention, at least one detection electrode 75 may be provided. While the detection electrodes may be provided in the seat bottom and the seatback, it is preferable to provide the detection electrode(s) in at least the seat bottom 71. The shape and dimensions of the detection electrode 75 are not particularly limited, but may be determined so as to match the size and shape of the seat bottom or seatback of the seat, or one or more electrodes may be provided only in portions of the seat with which the body of the occupant comes into contact when he/she is seated. The detection electrode may consist of a plurality of electrodes that are arranged in a pattern and electrically connected to each other. A lead wire is drawn from the detection electrode 75, and the detection electrode 75 is connected to the ECU 2, via an electric conductor (e.g., shielded cable) 23. Where the seat frame 76 is made of metal, the seat frame 76 that function as a ground electrode is connected to the ECU 2 via an electric conductor (e.g., a shield-side conductor of a shielded cable), and the potential of the seat frame 76 is referred to as “reference potential”.

FIG. 2 is a block diagram showing the configuration of the occupant detection system 1. FIG. 2 is an equivalent circuit diagram of the seat and an object on the seat, including a sensor portion 21 having the detection electrode 75 and the ground electrode 76, and C0, C1, R1. C0 represents capacitance that arises between the detection electrode 75 and the ground electrode 76 irrespective of whether an occupant is seated or not, and the capacitance C0 is developed by the seat and its surroundings, as well as the cushioning in the seat. When an occupant sits in the seat, the capacitance C0 may increase due to deformation of the seat, for example, as compared with the case where no occupant is seated. C1 and R1 constitute an equivalent circuit of an object, such as a human body, on the seat. When an occupant 9 is present in the seat, the body of the occupant is interposed between the detection electrode 75 and the ground. The human body is a dielectric, and has a larger dielectric constant than air; therefore, the capacitance C1 derived from the human body arises between the detection electrode 75 and the ground electrode 76, and the total capacitance between the electrodes increases significantly as compared with the case where no occupant is seated. In the meantime, the impedance around the detection electrode changes due to a disturbance factor, such as contact of the seat with water. In some cases, leakage current appears between the detection electrode 75 and the vehicle body via resistance R1. The leakage current increases when the seat gets wet.

The detection electrode 75 and ground electrode 76 provided in the sensor portion 21 are connected to the ECU 2 via the cable 23. The ECU 2 includes a power circuit 25, an oscillator circuit 41, two comparator circuits 43, 44, and a control circuit 6. The power circuit 25 produces DC power (such as voltages Va, Vb) supplied to each electronic circuit of the ECU 2, from power (such as a voltage of 12V) supplied from the battery of the vehicle. The outputs of the power circuit 25 may be Va that is equal to 8V, and Vb that is equal to 5V, for example.

The oscillator circuit 41 is connected to the detection electrode 75 with a resistive element Rb connected in series therebetween, and is adapted to output a reference signal S₀. The reference signal S₀ is a signal comprising a sinusoidal wave having a fixed frequency, and is formed by superimposing a given DC voltage (bias) on the sinusoidal wave. The bias value may be 0V. The DC bias value and the amplitude of the sinusoidal wave may be appropriately determined. For example, the oscillator circuit 41 may be arranged to use the above-indicated Va (8V) as power supplied, and generate a reference signal in the form of a sinusoidal wave having an amplitude of about 1-4V, to which a bias of 4V is given. While the frequency of the sinusoidal wave included in the reference signal S₀ is not particularly limited, it may be a fixed frequency within the range of several dozens of kHz to several hundreds of kHz. Preferably, the frequency may be within the range of 70 kHz to 200 kHz.

The reference signal S₀ generated from the oscillator circuit 41 is fed to the first comparator circuit 43. The comparator circuit 43 is configured to produce a digital reference phase signal D₀, by comparing the reference signal S₀ with a predetermined threshold value (Vr₀). The threshold value Vr₀ may be equal to the reference level of the sinusoidal wave included in the reference signal S₀, i.e., the above-mentioned bias value. The reference phase signal D₀ produced by the comparator circuit 43 is fed to the control circuit 6. Also, the detection electrode 75 is connected to the second comparator circuit 44. The comparator circuit 44 is configured to produce a digital electrode phase signal D₁, by comparing the potential of the detection electrode 75, i.e., a signal (electrode signal) S₁ of voltage developed between the ground electrode 76 and the detection electrode 75, with a threshold value (Vr₁). The electrode signal S₁ is a signal comprising a sinusoidal wave of the same frequency as that of the reference signal S₀ supplied to the detection electrode 75. The electrode phase signal D₁ produced by the comparator circuit 44 is fed to the control circuit 6.

The control circuit 6 measures delays in the timing of the electrode phase signal D₁ relative to the reference phase signal D₀, and performs an operation to determine whether an occupant is present in the seat, for example, based on the measurement results. The control circuit 6 may include input/output interfaces for transmitting the measurement values and determination results to the outside, such as an airbag system. The control circuit 6 may consist of a microcontroller (microcomputer adapted for incorporation) and its surrounding circuit. The control circuit 6 constituted by the microcontroller and others is adapted to store parameters, etc. used when determining whether an occupant is seated, for example, and includes programs used for performing or making measurements, control, setting of threshold values, determinations, and so forth. Thus, the control circuit 6 provides measuring means for measuring a delay time of a rise of the electrode phase signal D₁ relative to a rise of the reference phase signal D₀ as a rise delay time, and measuring a delay time of a fall of the electrode phase signal D₁ relative to a fall of the reference phase signal D₀ as a fall delay time, and detecting means for detecting a seated occupant based on the rise delay time and the fall delay time.

FIG. 3A to FIG. 3D are timing charts useful for explaining measuring operations of the occupant detection system. FIG. 3A represents the reference signal S₀ generated by the oscillator circuit 41. In this embodiment, the reference signal S₀ is in the form of a sinusoidal wave to which a bias of about one half of the power supply voltage Va is given. The reference signal S₀ is supplied to the detection electrode 75 via the resistive element Rb. The reference signal S₀ is also supplied to the comparator circuit 43. FIG. 3B represents the potential of the detection electrode 75, or the electrode signal S₁. The sinusoidal wave of the electrode signal S₁ has a different phase from that of the reference signal S₀, due to the capacitance between the ground electrode 76 and the detection electrode 75. The signal levels (the maximum value, the minimum value) of the electrode signal S₁ may be set by setting the value (resistance) of the resistive element Rb. The electrode signal S₁ is fed to the comparator circuit 44.

FIG. 3C represents the reference phase signal D₀ produced by comparing the reference signal S₀ with the threshold value Vr₀, in the first comparator circuit 43. In the example shown in FIG. 3, the reference phase signal D₀ becomes equal to logical “1” when the reference signal S₀ exceeds the threshold value Vr₀. The threshold value Vr₀ may be set to any value within the range between the maximum value and minimum value of the reference signal S₀. Preferably, the threshold value Vr₀ is set to a substantially middle level, i.e., the reference level of the sinusoidal waveform included in the reference signal S₀. In this manner, the reference phase signal D₀ that rises from “0” to “1” at point p₀₀ corresponding to the phase 0° of the sinusoidal waveform and falls from “1” to “0” at point p₀₁ corresponding to the phase 180° is produced. FIG. 3D represents the electrode phase signal D₁ produced by comparing the electrode signal S₁ with the threshold value Vr₁, in the second comparator circuit 44. In the example of FIG. 3D, the electrode phase signal D₁ becomes equal to logical “1” when the electrode signal S₁ exceeds the threshold value Yr₁. The threshold value Vr₁ is set so that the phases (p₁₀, p₁₁) at which the electrode signal S₁ passes the horizontal line of the threshold value Vr₁ are substantially equal to the phases at which the reference signal S₀ passes the line of the threshold value Vr₀. In this embodiment, the phases (p₀₀, p₀₁) at which the reference signal S₀ passes the horizontal line of the threshold value Vr₀ are 0° and 180°; therefore, the threshold value Vr₁ is set so that the horizontal line representing the threshold value Vr₁ passes points (p₁₀, p₁₁) at which the phase of the sinusoidal waveform included in the electrode signal S₁ becomes equal to 0° and 180°. Thus, the electrode phase signal D₁ that rises from “0” to “1” at point p₁₀ corresponding to the phase 0° of the electrode signal S₁ and falls from “1” to “0” at point p₁₁ corresponding to the phase 180° is produced.

The phase of the electrode signal S₁ is delayed from the phase of the reference signal S₀, due to the presence of the capacitance (C0+C1) between the detection electrode and the ground electrode. Therefore, the points in time at which the electrode phase signal D₁ rises and falls are delayed from the points in time at which the reference phase signal D₀ rises and falls. In FIG. 3A to FIG. 3D, a delay (in time) of a rise of the electrode phase signal D₁ relative to a rise of the reference phase signal D₀ is denoted as “rise delay time Tu”, and a delay (in time) of a fall of the electrode phase signal D₁ relative to a fall of the reference phase signal D₀ is denoted as “fall delay time Td”. Also, Ta represents the sum of the rise delay time Tu and the fall delay time Td. The rise delay time Tu and the fall delay time Td are substantially equal to each other in a situation where there is no disturbance factor like the seat being wet. In order to detect a seated occupant, for example, the rise delay time Tu, the fall delay time Td, or the sum Ta of Tu and Td may be used. Also, information about a seated occupant, contact of the seat with water, or the like, may be obtained from a combination of Tu, Td and Ta.

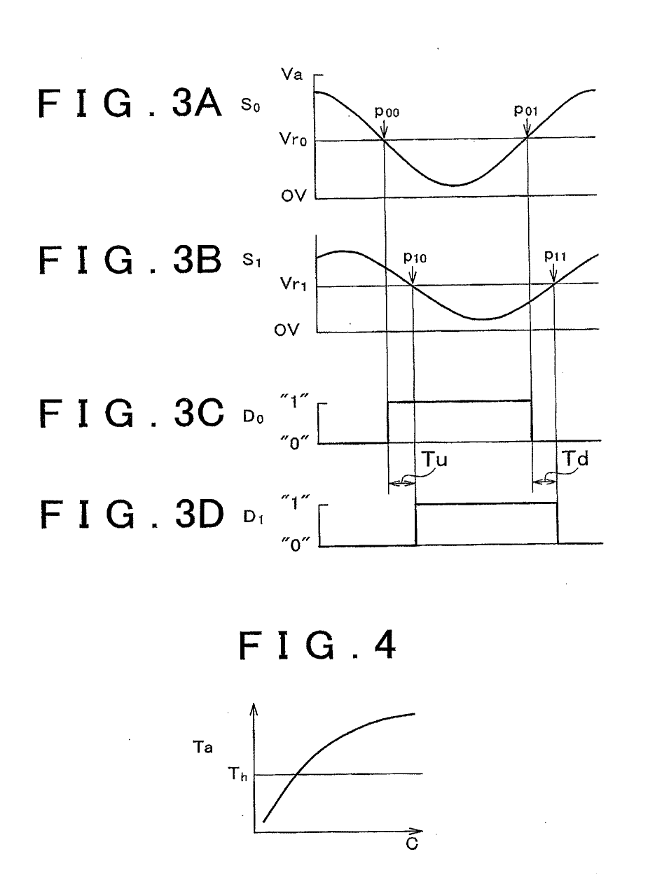

When an AC voltage of frequency f is supplied to a simple series circuit of capacitance C and resistance R, a phase delay φ of voltage derived from the capacitance C to the supplied voltage is calculated as φ=(n/2)−tan⁻¹(1/(2πfCR). Namely, the phase delay φ increases as the capacitance C increases. In one embodiment of the occupant detection system, where the phase difference of the electrode signal S₁ relative to the reference signal S₀ is measured as delay time (Ta), the delay time Ta and the capacitance C has a relationship as indicated in the graph of FIG. 4. Thus, the presence or absence of a seated occupant can be easily determined by comparing the measured delay time Ta with a predetermined threshold value Th.

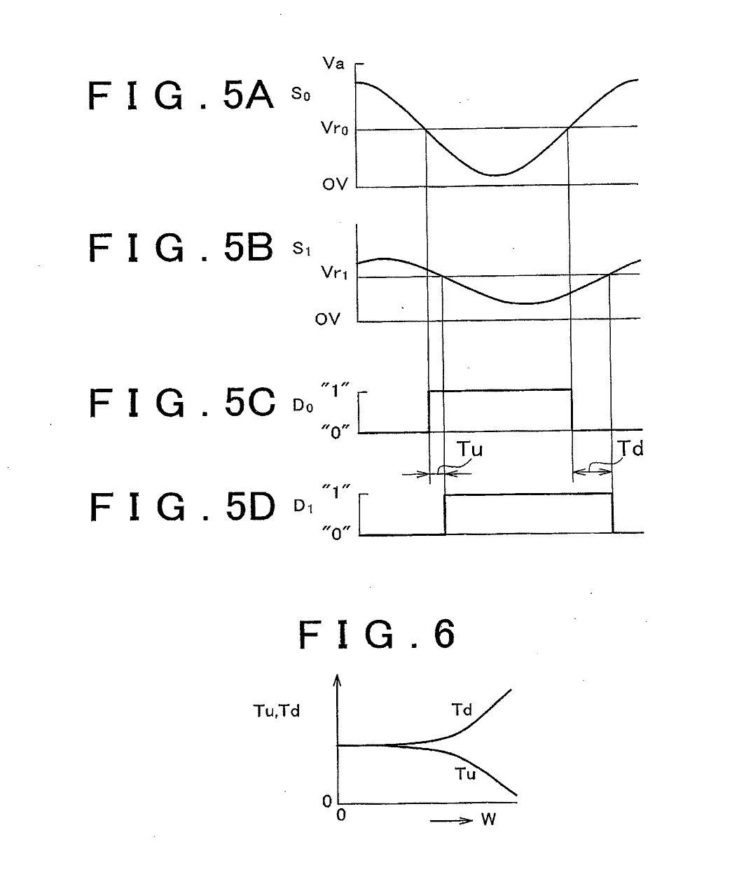

However, when the detection electrode 75 provided at the seat surface or immediately below the seat surface is in a wet condition, for example, the impedance around the detection electrode or between the detection electrode and the ground electrode changes. Also, leakage current increases, resulting in a reduction of the level of the electrode signal. S₁ and a reduction of the amplitude of the sinusoidal waveform. FIG. 5A to FIG. 5D show changes in the level of each signal in a condition where there is a disturbance factor, such as wetting of the detection electrode. In this condition, if the electrode signal S₁ is digitized using the same threshold value Vr₁ as that indicated in FIG. 3B, the timing of rise and fall of the electrode phase signal D₁ changes as shown in FIG. 5D. As a result, the rise delay time Tu decreases and the fall delay time Td increases, from those obtained in a condition where the seat is not wet, as shown in FIG. 3A to FIG. 3D. If the conductive cloth is used as the detection electrode 7, and the electrode portion gets wet, the rise delay time Tu and the fall delay time Td change as shown in FIG. 6, according to the amount W of water under which the seat is wet. Accordingly, the degree of wetness of the detection electrode portion of the seat can be determined from the amount of changes in the delay times Tu and Td.

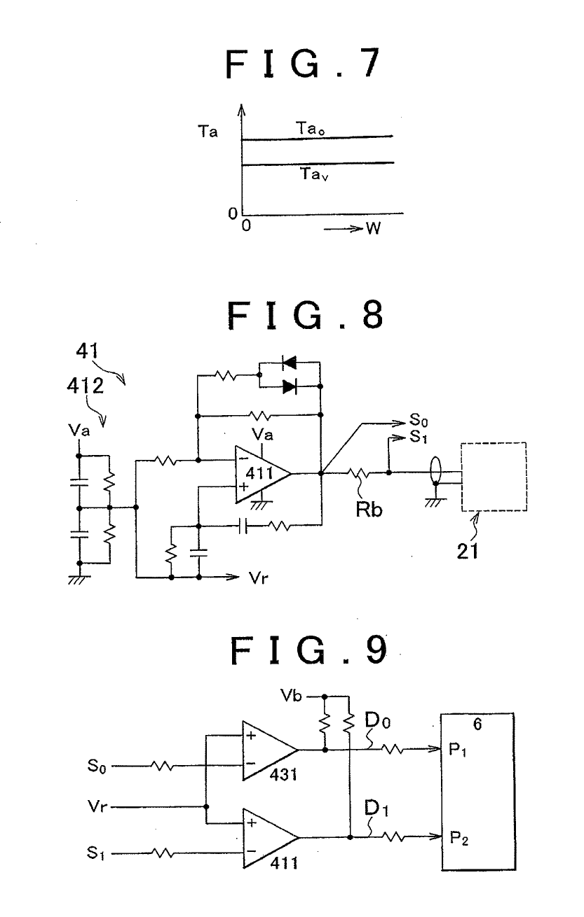

As shown in FIG. 6, in a condition where the seat is wet, the rise delay time Tu and the fall delay time Td change so as to substantially cancel each other out. Namely, it is found that the sum Ta of the rise delay time Tu and the fall delay time Td is almost constant, irrespective of whether the seat is wet or not, and irrespective of the degree of wetness of the seat. FIG. 7 shows the relationship between the sum Ta of the above-indicated delay times and the amount of water W under which the seat is wet. In FIG. 7, the vertical axis indicates time, and Ta_{V} is the above-indicated sum of delay times obtained when no occupant is present in the seat (i.e., the seat is vacant), while Ta_{O} is the sum of delay times obtained when an occupant is present in the seat. It will be understood that the sum Ta of delay times differs significantly depending on whether an occupant is seated or not, but does not change largely according to the amount of water W under which the seat is wet. Thus, the rise delay time Tu and the fall delay time Td are measured, and value Ta is obtained by adding Tu and Td together, so that it can be determined whether an occupant is present in the seat, irrespective of a wet condition of the seat, based on the thus obtained Ta.

The above-described operation and effect may be achieved by a further simpler arrangement. FIG. 8 shows a specific example of the oscillator circuit 41 using a known oscillator circuit. In this example, an oscillation frequency may be set to about 70 kHz, for example. The DC bias voltage (Vr) is generated by a potential divider 412. The reference signal S₀ produced by the oscillator circuit is transmitted to the detection electrode 75 included in the sensor portion 21, via the series resistance Rb. FIG. 9 shows specific examples of two comparator circuits 43 and 44. A comparator 431 that constitutes the first comparator circuit compares the reference signal S₀ generated from the oscillator circuit 41, with the DC voltage Vr produced by the potential divider 412, so as to produce a reference phase signal D₀, and sends the reference phase signal D₀ to the control circuit 6. A comparator 441 that constitutes the second comparator circuit compares the electrode signal S₁ generated at the detection electrode, with the DC voltage Vr produced by the potential divider 412, so as to produce an electrode phase signal D₁, and sends the electrode phase signal D₁ to the control circuit 6. The delay times Tu and Td of the electrode phase signal D₁ relative to the reference phase signal D₀ may be measured by the control circuit 6.

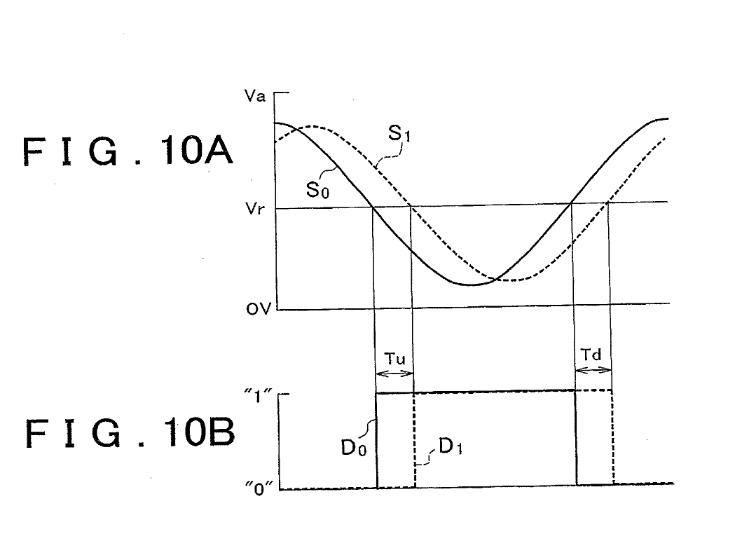

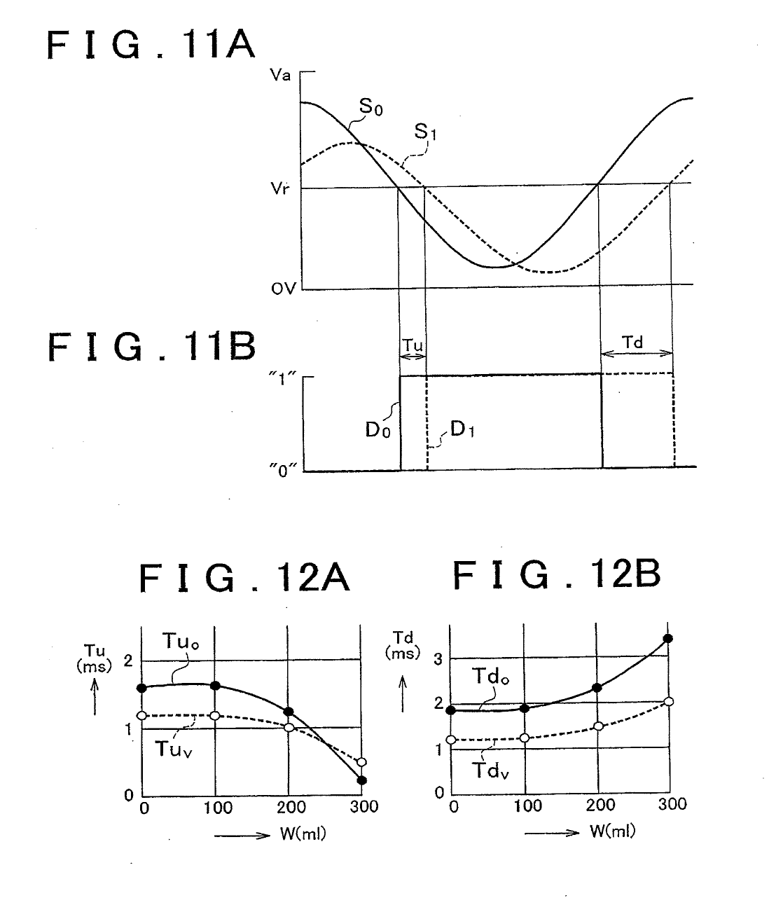

FIG. 10A and FIG. 10B are timing charts showing each signal obtained when the above-described circuits are used, in a normal condition where the seat is not wet, for example. By appropriately selecting the resistance value of the resistive element Rb, the levels (the maximum value and the minimum value) of the electrode signal S₁ may be made substantially equal to those of the reference signal S₀, as shown in FIG. 10A. As a result, the threshold value (Vr₀) used when creating the reference phase signal D₀ from the reference signal S₀ and the threshold value (Vr₁) used when creating the electrode phase signal D₁ from the electrode signal S₁ can be made equal to the same value Vr, and the oscillator and comparators can be provided by an extremely simple circuit. FIG. 11A and FIG. 11B are timing charts showing each signal obtained in a condition where there is a disturbance factor, such as a wet condition of the detection electrode portion. The levels (the maximum value and the minimum value) of the electrode signal S₁ are reduced due to the wet condition, for example. As a result, when the electrode signal S₁ is digitized using the predetermined threshold value Vr, the delay times Tu and Td of the electrode phase signal D₁ relative to the reference phase signal D₀ change from those in the condition as shown in FIG. 10A and FIG. 10B. Similarly to the case as described above, it is possible to determine the degree of wetness of the seat and the presence of a seated occupant, based on the delay times Tu, Td and the sum Ta of Tu and Td.

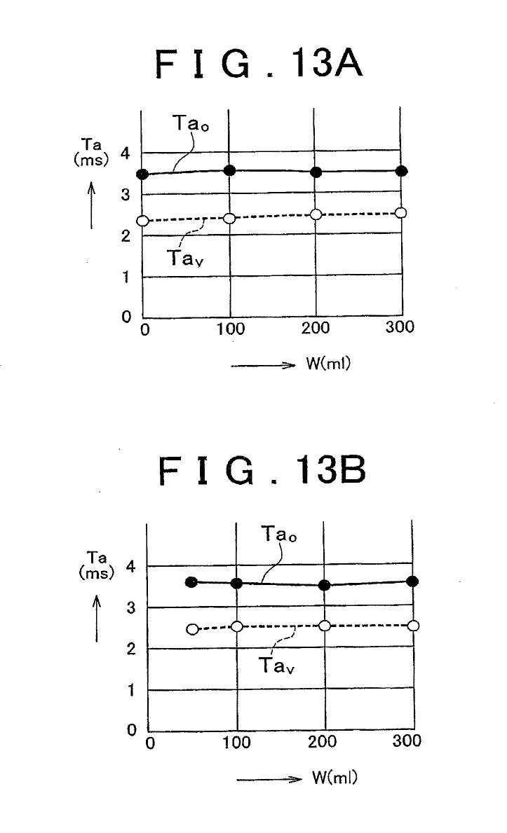

FIGS. 12A, 12B and FIGS. 13A, 13B are concerned with one example of the occupant detection system of the invention. In this example, a conductive cloth serving as a detection electrode was provided on a surface of the seat bottom of the seat. The size of the conductive cloth is 30 cm×40 cm, and stainless steel fibers are woven into the fabric at regular intervals of 5 mm. The conductive cloth was uniformly sprayed with water, to be brought into a wet condition, and the amount of water thus sprayed was indicated as the amount W (in ml) of water applied. The oscillator circuit and comparator circuits used in this example were those as shown in FIG. 8 and FIG. 9, and the frequency of the reference signal was 70 kHz, while the resistance of the resistive element Rb was 22 kΩ. FIG. 12A shows the relationship between the applied water amount W and the rise delay time Tu (in ins). In FIG. 12A, the broken line (Tu_{V}) indicates the rise delay time when no occupant is present in the seat (i.e., the seat is vacant), and the solid line (Tu_{O}) indicates the rise delay time when an occupant is present in the seat (i.e., the seat is occupied). FIG. 12B shows the relationship between the applied water amount W and the fall delay time Td (in ms). In FIG. 12B, the broken line (Td_{V}) indicates the fall delay time when no occupant is present in the seat, and the solid line (Td_{O}) indicates the fall delay time when an occupant is present in the seat. Since the rise delay time decreases and the fall delay time increases as the applied water amount increases, the degree of wetness of the seat can be determined from a difference therebetween, for example. FIG. 13A and FIG. 13B show the relationship between the sum Ta (in ms) of the rise delay time and the fall delay time, and the applied water amount W. In FIG. 13A and FIG. 13B, the broken line (Ta_{V}) indicates the sum of the delay times when no occupant is present in the seat, and the solid line (Ta_{O}) indicates the sum of the delay times when an occupant is present in the seat. FIG. 13A indicates measurement values obtained immediately after the seat gets wet, and FIG. 13B indicates measurement values obtained after a lapse of 10 min. from the time when the seat gets wet. It will be understood from the results that the sum Ta of the rise delay time and the fall delay time is almost constant irrespective of the applied water amount, even with a lapse of time, and therefore, the presence of an occupant in the seat can be stably or reliably determined from the sum Ta.

The occupant detection system according to the above-described embodiment of the invention includes the detection electrode 75, oscillator circuit 41 that supplies the sinusoidal reference signal S₀ to the detection electrode 75 via the resistive element Rb connected in series, first comparator circuit 43 that produces a binary reference phase signal D₀ by comparing the voltage of the reference signal S₀ with a predetermined threshold value, and the second comparator circuit 44 that detects the potential of the detection electrode 75 as the electrode signal S₁, and produces a binary electrode phase signal D₀ by comparing the electrode signal S₁ with a threshold value that is a value of the electrode signal S₁ at which the phase of the electrode signal S₁ is substantially the same as the phase of the reference signal S₀ at a point where the signal S₀ passes the above-indicated threshold value. The control method of the occupant detection system is a method of determining the presence or absence of a seated occupant or sensing a wet condition of the seat, using the detection electrode 75, oscillator circuit 41, first comparator circuit 43 and the second comparator circuit 44. The first comparator circuit 43 produces the reference phase signal D₀, using a voltage (Vr₀) at which the reference signal S₀ reaches a given phase p as a threshold value. The phase p corresponds to phases p₀₀, p₀₁ shown in FIG. 3A. On the other hand, the second comparison circuit 44 produces the electrode phase signal D₁, using a voltage (Vr₁) at which the electrode signal S₁ reaches the above-indicated phase p as the threshold value.

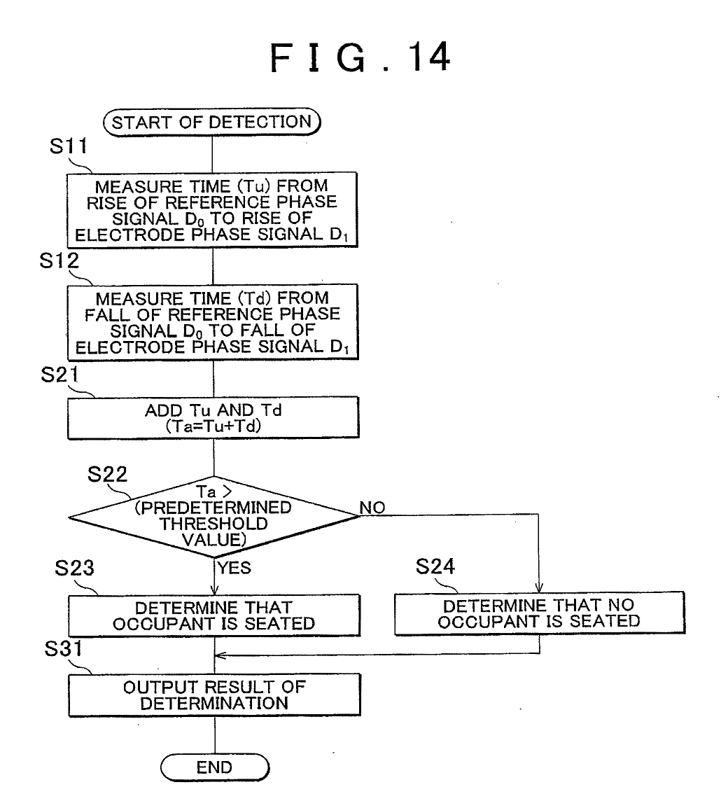

The occupant detection system includes a measuring step of measuring a delay time of a rise of the electrode phase signal D₁ relative to a rise of the reference phase signal D₀ as a rise delay time Tu, and measuring a delay time of a fall of the electrode phase signal D₁ relative to a fall of the reference phase signal D₀ as a fall delay time Td, and an occupant detecting step of detecting a seated occupant based on the rise delay time Td and the fall delay time Td. In the occupant detecting step, a seated occupant may be detected based on the sum Ta of the rise delay time Tu and the fall delay time Td. The occupant detection system may perform control as indicated in a flowchart of FIG. 14, for example. The control of FIG. 14 may be executed by the control circuit 6. In the above-mentioned measuring step, a delay time of a rise of the electrode phase signal D₁ relative to a rise of the reference phase signal D₀ is measured as a rise delay time Tu (step S11 in FIG. 14), and a delay time of a fall of the electrode phase signal D₁ relative to a fall of the reference phase signal D₀ is measured as a fall delay time Td (step S12). In the occupant detecting step, the sum Ta is obtained by adding the rise delay time Tu and the fall delay time Td (step S21), and the presence of an occupant in the seat may be determined based on the sum Ta. Namely, the value of the sum Ta is compared with a predetermined threshold value (step S22), and it is determined that an occupant is present in the seat if the value of Ta exceeds the threshold value (step S23). If not, it is determined that no occupant is present in the seat (step S24). The result of the determination may be delivered to the outside, such as an airbag system (step S31).

The occupant detection system may include a wetness detecting step of detecting a condition of disturbance, such as a wet condition of a seat, based on the rise delay time Tu and the rise fall delay time Td, in place of the occupant detecting step, so that the occupant detection system can be controlled in accordance with the degree of the disturbance, such as the degree of wetness of the seat. Here, the occupant detection system refers to a system that detects whether an occupant is present in the seat, by measuring the capacitance between electrodes provided in the vehicle seat, current, resistance, and so forth, and the configuration and determining method of the system are not limited. In the occupant detection system in which the detection electrode is provided on or immediately below the surface of the seat, the provision of the above-described oscillator circuit and the first and second comparator circuits makes it possible to determine a condition of disturbance, such as a wet condition of the seat, through the measuring step and the wetness detecting step. As shown in FIG. 6 and FIG. 12, as the amount of water under which the seat is wet increases, the rise delay time Tu decreases and the fall delay time Td increases according to the amount of water. Accordingly, the degree of disturbance, such as the degree of wetness of the seat, can be determined by measuring the rise delay time Tu and the fall delay time Td in the measuring step, and comparing Tu, Td, or a difference between Tu and Td with a predetermined reference value in the wetness detecting step. This makes it possible to correct the capacitance, current, resistance, and others measured by the occupant detection system, according to the degree of wetness of the seat, for example. It is also possible to change the operation of the occupant detection system, detection program, reference values and threshold values for use in determination, and so forth. Furthermore, if it is determined that a seated occupant cannot be normally detected due to a wet condition of the seat, for example, an alarm, or the like, may be generated.

It is to be understood that the invention is not limited to the above-described embodiments, but may be embodied with various changes or modifications within the range of the invention, depending upon the object and its use or application.

The system of the invention is widely used as an occupant detection system that determines whether an occupant is present in a vehicle seat. The system may also be used as a system for detecting a bed that is likely to get wet, or detecting a person sitting in a chair, or the like.

What is claimed is:

1. An occupant detection system, comprising:
a detection electrode provided in at least one of a seat bottom and a seatback of a vehicle seat;
an oscillator circuit that supplies a reference signal comprising a sinusoidal wave, to the detection electrode, via a resistive element;
a first comparator circuit that produces a binary reference phase signal by comparing the voltage of the reference signal with a first threshold value;
a second comparator circuit that detects the potential of the detection electrode as an electrode signal, and produces a binary electrode phase signal by comparing the electrode signal with a second threshold value, wherein the second threshold value is set so that a phase of the reference signal at a point at which the reference signal passes the first threshold value is substantially the same as that of the electrode signal at a point at which the electrode signal passes the second threshold value; and
a control circuit that includes a measuring unit that measures a delay time of a rise of the electrode phase signal relative to a rise of the reference phase signal as a rise delay time, and measures a delay time of a fall of the electrode phase signal relative to a fall of the reference phase signal as a fall delay time, and a detecting unit that detects an occupant based on the rise delay time and the fall delay time.

2. The occupant detection system according to claim 1, wherein the detecting unit determines the presence of a seated occupant based on the sum of the rise delay time and the fall delay time.

3. The occupant detection system according to claim 1, wherein the electrode signal is produced as a signal having substantially the same amplitude as that of the reference signal, and the second threshold value is set to the same value as the first threshold value.

4. The occupant detection system according to claim 1, wherein the detection electrode comprises a conductive cloth, and the conductive cloth is formed as a surface material of the seat, or is disposed immediately below the surface material.

5. The occupant detection system according to claim 4, wherein the conductive cloth is a woven fabric into which conductive fibers are woven at fixed intervals.

6. A control method of an occupant detection system including a detection electrode provided in at least one of a seat bottom and a seatback of a vehicle seat, an oscillator circuit that supplies a reference signal comprising a sinusoidal wave, to the detection electrode, via a resistive element, a first comparator circuit that produces a binary reference phase signal by comparing the voltage of the reference signal with a first threshold value, and a second comparator circuit that detects the potential of the detection electrode as an electrode signal, and produces a binary electrode phase signal by comparing the electrode signal with a second threshold value, wherein the second threshold value is set so that a phase of the reference signal at a point at which the reference signal passes the first threshold value is substantially the same as that of the electrode signal at a point at which the electrode signal passes the second threshold value, comprising:
measuring a delay time of a rise of the electrode phase signal relative to a rise of the reference phase signal as a rise delay time, and measuring a delay time of a fall of the electrode phase signal relative to a fall of the reference phase signal as a fall delay time; and
detecting a wet condition of the seat based on the rise delay time and the fall delay time.
